(19) United States
(12) Patent Application Publication
(10) Pub. No.: US 2019/0237308 A1
(43) Pub. Date: Aug. 1, 2019

(54) NON-CONTACT PHYSICAL ETCHING SYSTEM

(71) Applicant: Zavtrod Innovation Corporation, Hsinchu City (TW)

(72) Inventors: Cheng-Wei YANG, Hsinchu City (TW); Vladimir Sergeevich SUKHOMLINOV, Leningrad Region (RU)

(21) Appl. No.: 16/375,290

(22) Filed: Apr. 4, 2019

Related U.S. Application Data
(63) Continuation-in-part of application No. 14/643,033, filed on Mar. 10, 2015.

(30) Foreign Application Priority Data
Apr. 17, 2014 (TW) 103114094

(51) Int. Cl. H01J 37/32

(52) U.S. Cl. CPC H01J 37/32715; H01J 37/3244; H01J 37/32917; H01J 2237/202; H01J 2237/327; H01J 2237/002; H01J 2237/334

(57) ABSTRACT

Disclosures of the present invention describe a non-contact physical etching system, which consists of a main body, a separation member, a hollow chamber, a working gas supplying device, a plasma generating device, a first mask, and a target holder. Particularly, this non-contact physical etching system can be used for executing a direct physical etching process to a target put on the target holder, without treating the target with any photolithography processes in advance. Therefore, since this non-contact physical etching system is able to complete target etching by purely-physical way, it is extrapolated that the non-contact physical etching system can also be used for applying etching process to biomartials, medical substrates (for example, blood glucose test strip), and organic materials.

### CROSS-REFERENCE TO RELATED APPLICATIONS

This application is a continuation-in-part of U.S. patent application Ser. No. 14/643,033 filed on Mar. 10, 2015 and published as U.S. Patent Application Publication No. US2015-0303038A1 on Oct. 22, 2015. The above referenced application, and each document cited or referenced in the above referenced application, are hereby incorporated herein by reference.

### BACKGROUND OF THE INVENTION

### 1. Field of the Invention

The present invention relates to the field of plasma etching technologies, and more particularly to a non-contact physical etching system.

### 2. Description of the Prior Art

Etching process is a necessary and important manufacture process for the planar fabrication of the chips with integrated circuits and some micro-electromechanical components. Etching technologies have been known that can be mainly divided to dry etching process and wet etching process. Moreover, engineers skilled in wet etching technologies should know that, high selectivity with respect to a specific etching target is the most special feature of the wet etching technology. However, the occurrence of undercut resulted from isotropic etching is also well known that is the principal drawback when a wet etching process is applied to an etching target. As a result, the undercut causes that the wet etch technologies fail to be satisfy with the high requirement of narrow linewidth (<0.35 μm).

Plasma etching system is one of the most widely used dry etching technologies. FIG. 1 shows a cross-sectional view of a conventional plasma etching system disclosed by U.S. Pat. No. 4,691,662. The plasma etching system is one type of dual plasma microwave apparatus and has a main body 10′, wherein a base 30′ is provided with a quartz dish 15′ thereon, and is disposed in the main body 10′. Therefore, the main body 10′ is separated, by the base 30′, into a microwave cavity 11′ and a working space 41′. From FIG. 1, it is understood that there is a plasma region 16′ provided in the quartz dish 15′ for facing to the working space 41′. Moreover, a grid 17′ is connected to the quartz dish 15′, which is used for being as an microwave stopping member by covering the plasma region 16′.

According to the disclosures of U.S. Pat. No. 4,691,662, it is understood that a microwave is transmitted into the microwave cavity 11′ via a conduit 21′. In addition, by moving the sliding plate 12′ upwardly and downwardly, an inner volume of the microwave cavity 11′ can be properly adjusted so as to determine a transmission mode (TE or TM) of the microwave in the microwave cavity 11′. On the other hand, a ring-shaped tube 18′ is disposed in the base 30′, and is connected to an external gas feeding tube 19′. From FIG. 1, it can easily understand that a working gas is inputted into the plasma region 16′ through the gas feeding tube 19′ and the ring-shaped tube 18′, such that the working gas is transformed to plasma by the high-energy microwave.

Moreover, FIG. 1 also depicts that the grid 17′ is electrically connected to a first voltage source 34′, and an article 43′, biased by a second voltage source 44′, is putted on a holder 39′ arranged in the working space 41′. As described in detail below, ions or electrons from the plasma formed in the plasma region 16′ are accelerated by the first voltage source 34′, such that the accelerated charges pass through the grid 17′ and then move toward the article 43′. It is worth noting that. the sliding plate 12′ and the quartz dish 15′ are two terminal end of the microwave cavity 11′, and the grid 17′ is configured for preventing the high-energy microwave from getting into the working space 41′. Therefore, engineers skilled in development and manufacture of the plasma etch systems would know that, the grid 17′ must be particularly designed to have a specific opening ratio, such that atoms, molecules, free radicals, electrons, and ions are allowed to flow or diffuse from the plasma region 16′ to the working space 41′ via the grid 17′, so as to make the plasma region 16′ has a plasma forming environment therein with an adequate low air pressure.

As FIG. 1 shows, when the plasma etching system is in operation, atoms, molecules, free radicals, electrons, and ions in the plasma transformed from the working gas continuously move to the surface of the article 43′ after pass through the grid 17′, so as to consequently lead at least one chemical reaction to occur on the article 43′. For example, if SiH₄ is used as the working gas, molecules and/or the atoms in the plasma transformed from the SiH₄ will achieve a chemical deposition on the surface of the article 43′. On the other hand, if CF₄ is adopted for being as the working gas, free radicals, electrons, and/or ions in the plasma transformed from the CF₄ will apply a chemical etching to the surface of the article 43′.

It needs to particularly note that, there is merely one vacuum pump 47′ integrated in the plasma etching system shown in FIG. 1. During the normal operation of the plasma etching system, the vacuum pump 47′ works for continuously pumping the working gas out of the main body 10′, such that the working gas in the plasma region 16′ is attracted so as to eventually get into the vacuum pump 47′ by way of passing through the grid 17′, moving into the working space 41′ and flowing into a gas tube connected between the vacuum pump 47′ and the main body 10′. Therefore, it is easily understand that, an actual air pumping rate of the vacuum pump 47′ with respect to the working gas in the plasma region 16′ is certainly limited by the opening ratio of the grid 17′. As described in detail below, the working gas is inputted into the plasma region 16′ via the gas feeding tube 19′ and the ring-shaped tube 18′ during the normal operation of the plasma etching system, so that a hydrostatic equilibrium of the working gas certainly occurs in the case of an inflow rate and an outflow rate being equal to each other. However, when the inflow rate with respective to the plasma region 16′ is controlled to be constant, the outflow rate limited by opening ratio of the grid 17′ is difficult to be equal to the outflow rate in the plasma region 16′. In such case, the air pressure in the plasma forming environment of the plasma region 16′ is certainly increased so as to enhance an air pressure difference between the plasma region 16′ and the working space 41′, in order to achieve the hydrostatic equilibrium of the working gas. Briefly speaking, the opening ratio of the grid 17′ is found to simultaneously affect the air pressure in the plasma forming environment of the plasma region 16′, thereby influencing the quality or stability of the plasma formed in the plasma region 16′.

From above descriptions, it is further extrapolated that, since the air pressure in the plasma forming environment of the plasma region 16′ is increased due to the influence of the opening ratio of the grid 17′, the vacuum pump 47′ is unable to make the plasma forming environment in the plasma region 16′ have an adequate low air pressure because the actual air pumping rate of the vacuum pump 47′ is limited by grid 17′. As described in detail below, despite that an air pumping rate of the vacuum pump 47′ is set to 100 L/min, a maximum flow rate of the working gas passing through the grid 17′ may be only 10 L/min due to the limitation caused by the opening ratio of the grid 17′. In such case, if the inflow rate of the plasma region 16′ is 20 L/min, the air pressure in the plasma forming environment of the plasma region 16′ must be increased to be P2=(20/10)×P1, in order to achieve a hydrostatic equilibrium in the plasma region 16′. Herein, P2 means the air pressure in plasma region 16′, and P1 represents the air pressure in working space 41′.

From above descriptions, engineers skilled in development and manufacture of plasma etching system should know that, degree of vacuum of the plasma forming environment in the plasma region 16′ as well as the formation and quality of plasma transformed from the working gas would not be affect by grid 17′ as long as the opening ratio of the grid 17′ is high enough. However, it is worth noting that, the grid 17′ with high opening ratio cannot be directly adopted for being as an etching mask for the article 43′ disposed in the holder 39′. That means the article 43′ is provided with a patterned photoresistor thereon before being disposed on the holder 39′. As a result, specific portions of the article 43′ that not been covered by the patterned photoresistor would be etched by the chemical etching applied by the plasma transformed from the CH₄.

Needing to have an enough high opening ratio is the principal reason that the line width of a specific etching pattern made on the grid 17′ (i.e., the etching mask) cannot be designed to too narrow. For instance, it is easy to manufacture a grid 17′ (i.e., the etching mask) by forming 100 perforation groove lines on a substrate or plate with 8 inches diameter. However, if each of the 100 perforation groove lines has a line width of 10 μm, the grid 17′ will have an opening ratio of 0.005. It is foreseeable that the opening ratio of 0.005 certainly affects the degree of vacuum of the plasma forming environment in the plasma region 16′ as well as the formation of plasma seriously.

On the other hand, the grid 17′ with high opening ratio still exhibits some drawbacks in practical use. The grid 17′ with high opening ratio may allow the high-energy microwave and the plasma transformed from the working gas to further diffuse into the working space 41′. In such case, the plasma region 16′ and the working space 41′ together form a plasma container in the main body 10′, such that the chemical etching carried out on the surface of the article 43′ and applied by free radicals, electrons, and/or ions in the plasma transformed from the CF₄ is hence affected. Moreover, electrical arc might occur on the holder 39′ and a holder moving mechanism arranged in the working space 41′ due to the influences of the high-energy microwave and the plasma, causing the plasma to be unstable.

Engineers skilled development and manufacture of plasma etching system should know that, the air pressure (i.e., degree of vacuum) of a plasma forming environment does seriously affect the formation and quality of a plasma transformed from a working gas. For example, U.S. Patent Publication No. 20140302680A1 has disclosed internal plasma grids for use in semiconductor dry etching apparatus. According to the disclosure of the U.S. Patent Publication No. 20140302680A1, multi plasma grids with different opening ratios are arranged in chamber of a plasma dry etching apparatus for controlling or modulating the formation and properties of the plasma.

FIG. 2 shows a cross-sectional view of an improved plasma etching system disclosed by U.S. Pat. No. 6,077,787 (hereinafter '787). As FIG. 2 shows, '787 disclosed a plasma etching system for improving the above-described shortcomings of the plasma etching system taught by U.S. Pat. No. 4,691,662 (hereinafter '662). After comparing FIG. 1 and FIG. 2, it is very clear that the plasma etching system taught by '787 is almost the same plasma etching system as the system taught by '662, except for that the '787 particularly teaches a smaller microwave cavity 11′ and a larger plasma disk 16′. Moreover, '787 has removed the grid 17′ from the main body 10′. What is worth thinking is that “why '787 removes the grid 17′ from the plasma etching system taught by '662?”. The principal reason is that, the opening ratio of the grid 17′ used in the plasma etching system cannot be designed to too low.

From the disclosures of U.S. Pat. No. 6,077,787, it is known that the density of the plasma formed in the plasma region 16′ is enhanced with the increase of the energy of the microwave. Moreover, it can also know that variation of the air pressure in the plasma region 16′ would obviously affect the density and potential of the plasma.

However, although the improved plasma etching system is not integrated with the grid 17′, the improved plasma etching system still cannot be configured for carrying out a physical etching on the surface of the article 43′. In the case of lacking the shielding provided by the grid 17′, the high-energy microwave and the plasma transformed from the working gas to would directly flow into the working space 41′. In such case, the plasma region 16′ and the working space 41′ together form a plasma container in the main body 10′, such that the chemical etching carried out on the surface of the article 43′ and applied by free radicals, electrons, and/or ions in the plasma transformed from the CF₄ is hence affected. Moreover, electrical arc might occur on the holder 39′ and a holder moving mechanism arranged in the working space 41′ due to the influences of the high-energy microwave and the plasma, causing the plasma to be unstable.

In conclusion, currently-disclosed plasma etching system(s) fails to be configured for achieving a direct physical etching on the surface of the article 43′. CF₄ is mainly adopted for being as the working gas when the conventional plasma etching system is operated to execute a dry etching process to the article 43′. During the normal operation of the plasma etching system, free radicals, electrons, and/or ions in the plasma transformed from the CF₄ apply a chemical etching to the surface of the article 43′. Besides, although some advanced etching technologies including electron beam etch, focused ion beam (FIB) etch and excimer laser etch have been entirely developed, the currently-used electron beam etching apparatus, FIB etching apparatus and excimer laser etching apparatus have an identical drawback of being unable to be applied to achieve mass production etching process. Moreover, another drawback of the laser etching apparatus is that its etching accuracy is limited to 10 μm. Opposite to the laser etching apparatus, the beam etching apparatus have another drawback of over expensive vacuum equipment.

From above descriptions, it is clear that how to design and develop a novel plasma etching system capable of achieving a non-contact physical etching on an etching target has become an important issue. In view of that, inventors of the present application have made great efforts to make inventive research and eventually provided a non-contact physical etching system.

### SUMMARY OF THE INVENTION

The primary objective of the present invention is to disclose a non-contact physical etching system, which mainly comprises: a main body, a separation member, a hollow chamber, a working gas supplying device, a plasma generating device, a first mask, and a target holder. Particularly, this non-contact physical etching system can be used for executing a direct physical etching process to a target put on the target holder, without treating the target with any photolithography processes in advance. Moreover, during the normal operation of the non-contact etching process, the plasma in the hollow chamber would produce a spontaneous electric field near the surface of the first mask for maintaining an electrical neutrality therein, such that the spontaneous electric field accelerates charges in the plasma to move, so as to pass through at least one first pattern formed on the first mask. As a result, the accelerated charges move to the target and then etch or cut the target by direct bombardment. Because this non-contact physical etching system is able to complete target etching by purely-physical way, it is extrapolated that the non-contact physical etching system can also be used for applying etching process to biomartials, medical substrates (for example, blood glucose test strip), and organic materials.

In order to achieve the primary objective of the present invention, the inventor of the present invention provides an embodiment for the non-contact physical etching system, comprising:
a main body having an internal space;
a separation member, being disposed in the main body for partitioning the internal space into a first chamber and a second chamber;
a hollow chamber, being disposed on the separation member, and having a first opening located in the first chamber and a second opening located in the second chamber;
a first mask connected to the hollow chamber for shielding the second opening, wherein the first mask comprises a first metal substrate that are provided with a plurality of first perforation grooves thereon;
a target holder, being disposed in the second chamber 2 for supporting at least one etching target;
a first vacuum pump, being connected to the first chamber for making the first chamber and the hollow chamber both have a first air pressure;
a second vacuum pump, being connected to the second chamber for making the second chamber has a second air pressure;
a plasma generating device, being connected to the first chamber; wherein the plasma generating device is adopted for supplying a plasma into the first chamber, or is configured for making a plasma be formed in the first chamber;
a working gas supplying device, being connected to the first chamber and the plasma generating device;
wherein the plasma in the first chamber would flow into the hollow chamber via the first opening;
wherein the first mask is used as an exciting member of the plasma in the hollow chamber, such that the plasma is excited so as to produce a spontaneous electric field near a top surface of the first mask for achieving an electrical neutrality therein;
wherein a plurality of charges in the plasma are accelerated by the spontaneous electric field, so as to move and then pass through at least one first perforation pattern constituted by the plurality of first perforation grooves, thereby etching or cutting the etching target on the target holder by direct bombardment.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows a cross-sectional view of a conventional plasma etching system disclosed by U.S. Pat. No. 4,691,662;

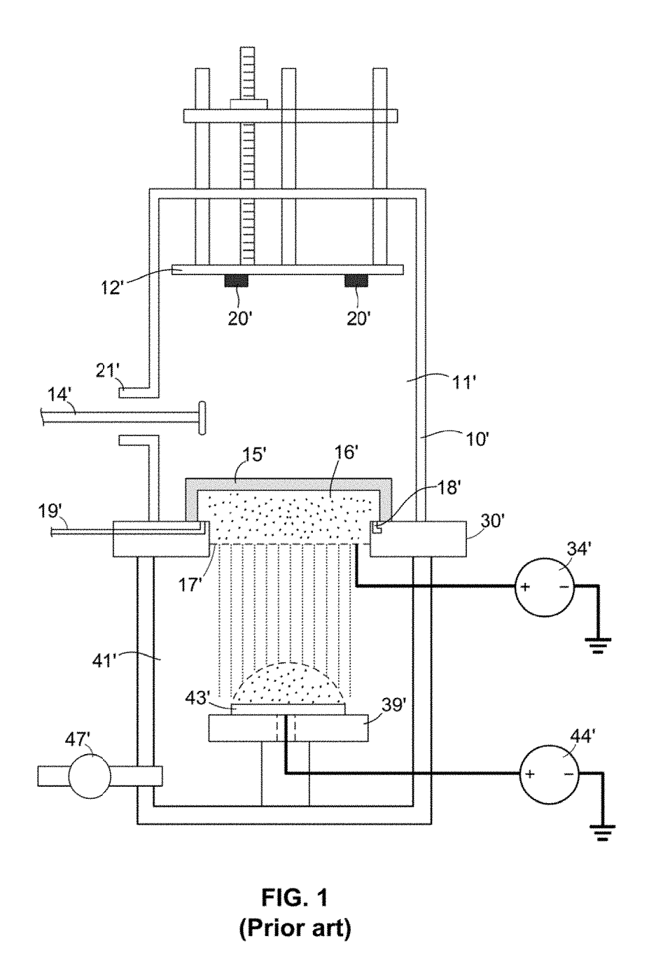

FIG. 2 shows a cross-sectional view of an improved plasma etching system disclosed by U.S. Pat. No. 6,077,787;

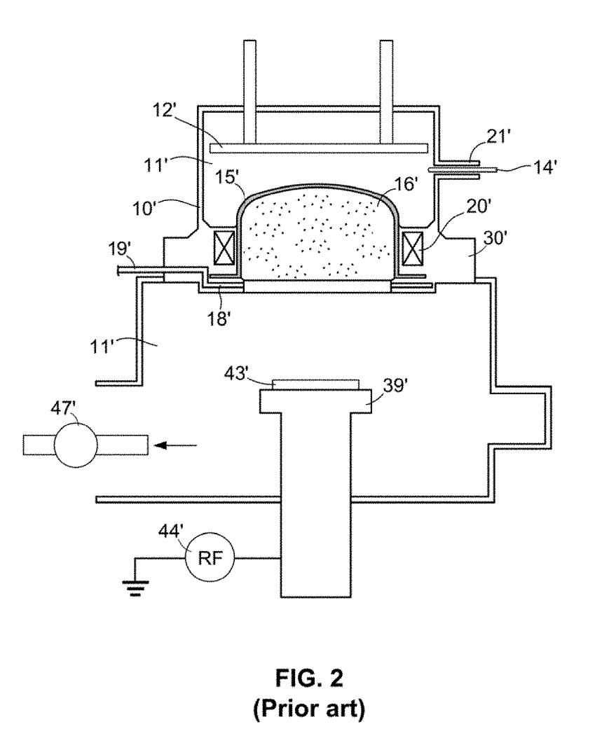

FIG. 3 shows a cross-sectional view of a first embodiment of a non-contact physical etching system according to the present invention;

FIG. 4 shows stereo diagrams of a main body, a separation member, a hollow chamber, a first mask, a target holder, a first vacuum pump, and a second vacuum pump;

FIG. 5 shows a top view of the first mask and an etching target;

FIG. 6 shows a schematic diagram for describing applications of the first mask;

FIG. 7 shows a cross-sectional view of a second embodiment of the non-contact physical etching system according to the present invention;

FIG. 8 shows a cross-sectional view of a third embodiment of the non-contact physical etching system according to the present invention; and

FIG. 9 shows a cross-sectional view of a fourth embodiment of the non-contact physical etching system according to the present invention.

### DETAILED DESCRIPTION OF THE PREFERRED EMBODIMENTS

To more clearly describe a non-contact physical etching system disclosed by the present invention, embodiments of the present invention will be described in detail with reference to the attached drawings hereinafter.

### First Embodiment

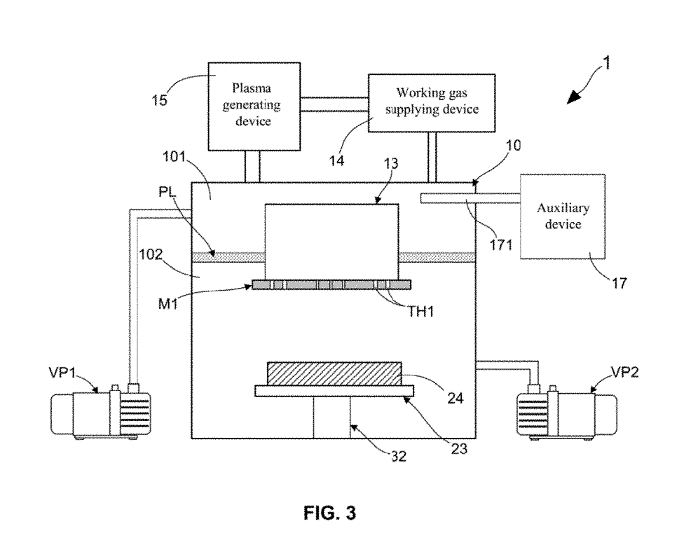

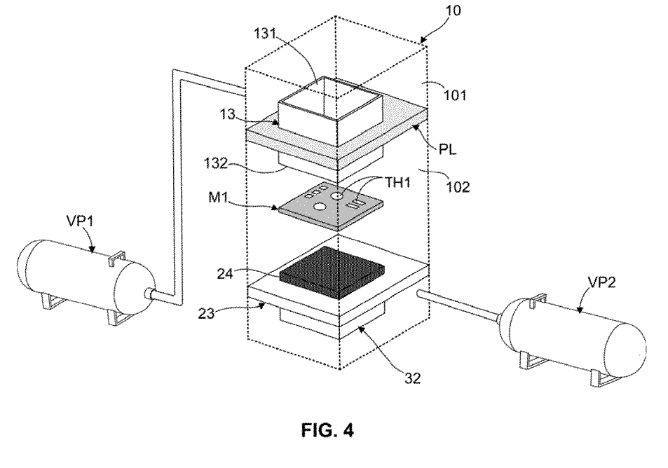

With reference to FIG. 3, there is shown a cross-sectional view of a first embodiment of a non-contact physical etching system according to the present invention. As FIG. 3 shows, the non-contact physical etching system 1 of the present invention comprises: a main body 10, a separation member PL, a hollow chamber 13, a first mask M1, a target holder 23, a first vacuum pump VP1, a second vacuum pump VP2, a plasma generating device 15, and a working gas supplying device 14. Moreover, FIG. 4 shows stereo diagrams of the main body 10, the separation member PL, the hollow chamber 13, the first mask M1, the target holder 23, the first vacuum pump VP1, and the second vacuum pump VP2. According to the particular design of the present invention, the a main body 10 hasg an internal space, and the separation member PL is disposed in the main body 10 for partitioning the internal space into a first chamber 101 and a second chamber 102. On the other hand, the hollow chamber 13 is disposed on the separation member PL, and has a first opening 131 located in the first chamber 101 and a second opening 132 located in the second chamber 102.

It needs to particularly explain that, the first mask M1 is connected to the hollow chamber 13 for shielding the second opening 132, and the first mask M1 comprises a first metal substrate that are provided with a plurality of first perforation grooves TH1 thereon. According to the particular design of the present invention, each of the plurality of first perforation grooves TH1 has a groove width smaller than 100 μm, and the first mask M1 has an opening ratio smaller than 60%. By such arrangements, it is not only at least one first perforation pattern constituted by the plurality of first perforation grooves TH1 can be directly adopted for being as an etching pattern, but also a plasma in the hollow chamber 13 can be blocked by the first mask M1 from diffusing or flowing into the second chamber 102.

The target holder 23 is disposed in the second chamber 102 for supporting at least one etching target 24. Moreover, the first vacuum pump VP1 is connected to the first chamber 101 for making the first chamber 101 and the hollow chamber 13 both have a first air pressure. On the other hand, the second vacuum pump VP2 is connected to the second chamber 102 for making the second chamber 102 has a second air pressure. From FIG. 3 and FIG. 4, it is understood that the plasma generating device 15 is connected to the first chamber 101, so as to be adopted for supplying a plasma into the first chamber 101, or be configured for making a plasma be formed in the first chamber 101. Besides, the working gas supplying device 14 is connected to the first chamber 101 and the plasma generating device 15.

After the plasma is supplied into or directly formed in the first chamber 101, the plasma would flow into the hollow chamber 13 via the first opening 131, and then is blocked from the first mask M1 from being subsequently flowing into the second chamber 102. In this case, the first mask M1 comprising a first metal substrate is configured as an exciting member of the plasma in the hollow chamber 13, such that the plasma is excited so as to produce a spontaneous electric field near a top surface of the first mask M1 for achieving an electrical neutrality therein. As a result, a plurality of charges in the plasma are accelerated by the spontaneous electric field, so as to move and then pass through at least one first perforation pattern constituted by the plurality of first perforation grooves TH1, thereby etching or cutting the etching target 24 on the target holder 23 by direct bombardment.

FIG. 3 also depicts that the non-contact physical etching system 1 further comprises an auxiliary device 17, wherein a detection unit 171 of the auxiliary device 17 disposed in the first chamber 101 for measuring a temperature parameter and a plasma parameter. As described in detail below, it is easy for the engineers to monitor the temperature parameter and the plasma parameter such as density or potential of the plasma by using the auxiliary device 17. Therefore, engineers are able to make the density and/or potential of the plasma in the hollow chamber 13 by operating the first vacuum pump VP1 to control the first air pressure of the first chamber 101, or modulating an output power of the plasma generating device 15. It is worth noting that, since the first chamber 101 and the second chamber 102 are isolated by the separation member PL as well as the second opening is covered by the first mask M1, the first perforation pattern constituted by the plurality of first perforation grooves TH1 and/or a low opening ratio would not become the factors for affecting the first air pressure. Briefly speaking, the first air pressure can be directly controlled by the first vacuum pump VP1, and would not be affected by the line width of the first perforation grooves TH1 and/or the opening ratio of the first mask M1.

As described in detail below, if the opening ratio of the first mask M1 is set to a low value, the working gas supplied by the working gas supplying device 14 is limited by the first mask M1, such that it is very difficult for the working gas in the first chamber 101 or the hollow chamber 13 to naturally flow into the second chamber 102 via the first mask M1. In this case, the first air pressure in the first chamber 101 can be directly controlled by properly modulating an air pumping rate of the first vacuum pump VP1. As a result, quality or stability of the plasma in the hollow chamber 13 is therefore not influenced by the line width of the first perforation grooves TH1 and/or the opening ratio of the first mask M1. On the other hand, FIG. 3 also depicts that a thermal dissipation device 34 is set for applying a heat dissipating process to the hollow chamber 13, the target holder 23 and the etching target 24. In addition, a holder moving device 32, being used for driving the target holder 23 to move corresponding to the first mask M1 under a precise alignment.

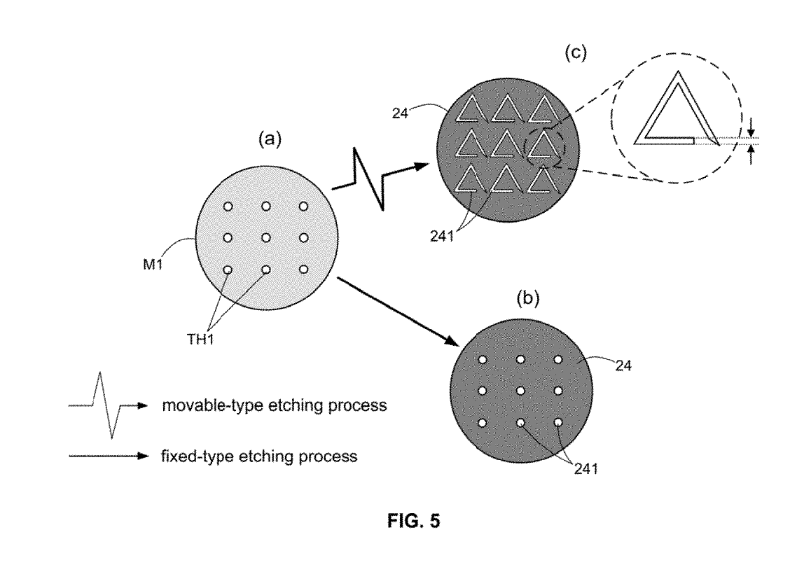

FIG. 5 shows a top view of the first mask and an etching target. From FIG. 5, it is found that a first perforation grooves TH1 are arranged to an array on the first mask M1. By the use of the first mask M1, this non-contact physical etching system 1 can be operated for carrying out a fixed-type etching process on the etching target 24. As diagrams (a) and (b) of FIG. 5 show, the charges in the plasma are accelerated by the spontaneous electric field, so as to physically etch the etching target 24 on the target holder 23 by direct bombardment after passing through the first perforation pattern constituted by the plurality of first perforation grooves TH1. As a result, there is a specific pattern 241 the same as the first perforation pattern formed on the etching target 24. Moreover, by the use of the first mask M1 and the holder moving device 32, this non-contact physical etching system 1 can also be operated for carrying out a movable-type etching process on the etching target 24. As diagrams (a) and (c) of FIG. 5 show, the charges in the plasma are accelerated by the spontaneous electric field, so as to physically etch the etching target 24 on the target holder 23 by direct bombardment during the target holder 23 being driven by the holder moving device 32 to move along a specific path. As a result, there is another one specific pattern 241 formed on the etching target 24. As diagram (a) of FIG. 5 shows, the line width of the perforation groove TH1 is the same as the line width of the pattern 241, that means it is going to make any one type of pattern one etching target 24 by using this non-contact physical etching system. Moreover, the line width of the pattern 241 can be easily determined by the line width of the perforation groove TH1.

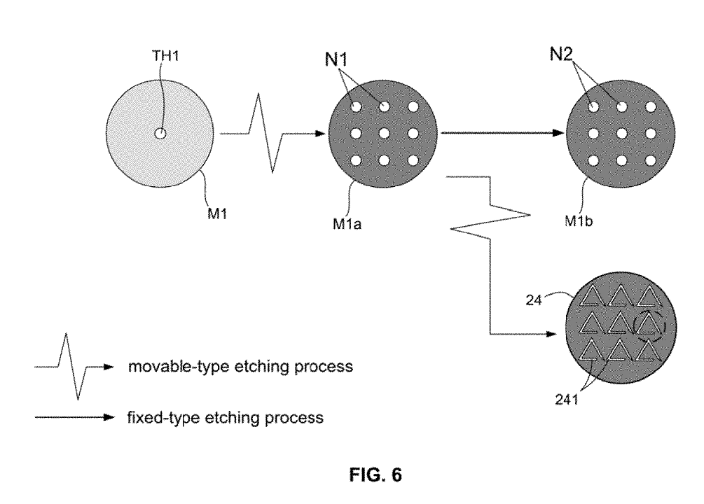

FIG. 5 also depicts that the first perforation groove TH1 has an overlooking shape, and the overlooking shape is a circle shape. However, it is easily extrapolated that the overlooking shape can also be a line shape, a regular curve shape, an irregular curve line shape, an oval shape, a triangle shape, a square shape, or a polygonal shape. FIG. 6 shows a schematic diagram for describing applications of the first mask. As FIG. 6 shows, there is only one first perforation groove TH1 formed on the first mask M1. By the use of this first mask M1, the non-contact physical etching system 1 can be operated for carrying out a fixed-type etching process on an substrate, so as to process the substrate to a base mask M1a having a perforation groove array N1. Furthermore, a copied mask M1a of the base mask M1a can be manufactured by operating the non-contact physical etching system 1 to finish a fixed-type etching process onto another one substrate under the use of the base mask M1a.

### Second Embodiment

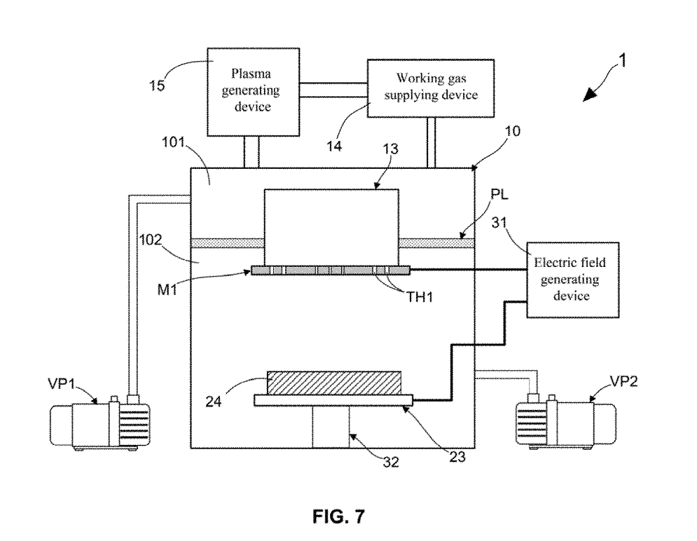

With reference to FIG. 7, there is shown a cross-sectional view of a second embodiment of the non-contact physical etching system according to the present invention. After comparing FIG. 7 with FIG. 3, it is easily found that the second embodiment further comprises an electrical field generating device 32, being electrically connected to the first mask M1 and the target holder 23, which is configured for forming an electrical field between the first mask M1 and the target holder 23 for speeding the charges.

### Third Embodiment

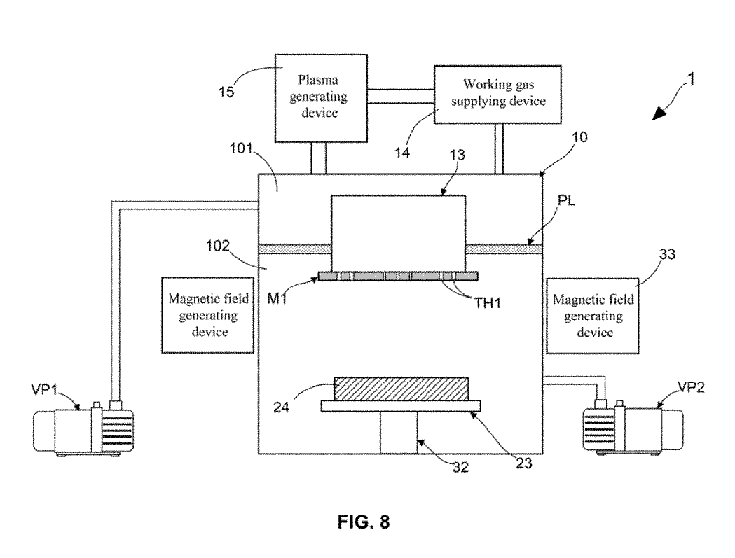

With reference to FIG. 8, there is shown a cross-sectional view of a third embodiment of the non-contact physical etching system according to the present invention. After comparing FIG. 8 with FIG. 3, it is easily found that the third embodiment further comprises a magnetic field generating device 33, and which is configured for providing a magnetic field in the second chamber 102.

### Fourth Embodiment

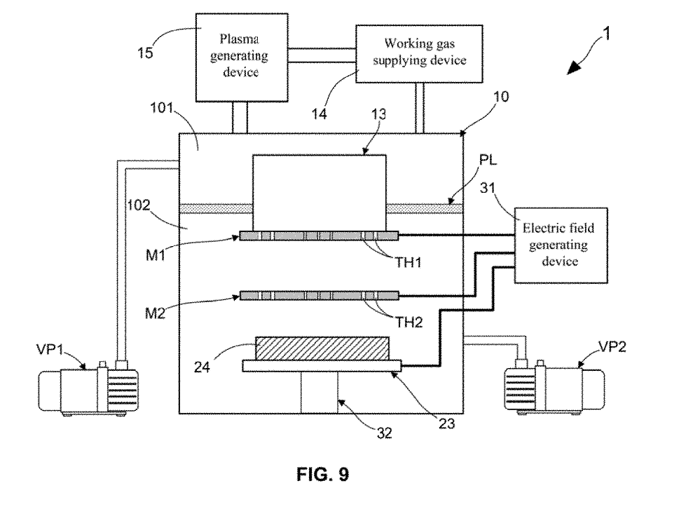

With reference to FIG. 9, there is shown a cross-sectional view of a fourth embodiment of the non-contact physical etching system according to the present invention. After comparing FIG. 9 with FIG. 3, it is easily found that the fourth embodiment further comprises a second mask M2 disposed between the first mask M1 and the etching target 24, wherein the second mask M2 comprises a second metal substrate that are provided with a plurality of second perforation grooves TH2 thereon. It is worth noting that, in the case of the second perforation pattern being the same as the first perforation pattern, the charged accelerated by the spontaneous electric field is converged by the second mask, so as to be prevented from being subject to lateral divergence. However, in another case that the second perforation pattern is different from the first perforation pattern, a relative intersection between the second perforation pattern and the first perforation pattern form a third perforation pattern. For instance, both the first perforation pattern and the second perforation pattern can be particularly designed to a narrow perforation line array, such that third perforation pattern would be a perforation groove array as long as each of relatively included angles between the narrow perforation line array of the first perforation pattern and the narrow perforation line array of the second perforation pattern and the is close to 90°.

Therefore, through above descriptions, all embodiments and their constituting elements of the non-contact physical etching system proposed by the present invention have been introduced completely and clearly; in summary, the present invention includes the advantages of:

(1) The present invention describes a non-contact physical etching system 1, which consists of a main body 10, a hollow chamber 13, a separation member PL, a working gas supplying device 14, a plasma generating device 15, a first mask M1, and a target holder 23. Particularly, this non-contact physical etching system 1 can be used for executing a direct physical etching process to an etching target 24 put on the target holder 23, without treating the etching target 24 with any photolithography processes in advance.

(2) Moreover, during the normal operation of the non-contact etching process 1, the plasma in the hollow chamber 13 would produce a spontaneous electric field near the surface of the first mask M1 for maintaining an electrical neutrality therein, such that the spontaneous electric field accelerates charges in the plasma to move, so as to pass through at least one first pattern formed on the first mask M1. As a result, the accelerated charges move to the etching target 24 and then etch or cut the etching target 24 by direct bombardment. Because this non-contact physical etching system 1 is able to complete a target etching by purely-physical way, it is extrapolated that the non-contact physical etching system 1 can also be used for applying etching process to biomartials, medical substrates (for example, blood glucose test strip), and organic materials.

(3) According to the particular design of the present invention, each of the plurality of first perforation grooves TH1 has a groove width smaller than 100 μm, and the first mask M1 has an opening ratio smaller than 60%. By such arrangements, it is not only at least one first perforation pattern constituted by the plurality of first perforation grooves TH1 can be directly adopted for being as an etching pattern, but also the plasma in the hollow chamber 13 can be blocked by the first mask M1 from diffusing or flowing into the second chamber 102. Therefore, the air pressure in the hollow chamber 13 and the first chamber 101 can be directly controlled by the first vacuum pump VP1, and would not be affected by the line width of the first perforation grooves TH1 and/or the opening ratio of the first mask M1. As a result, quality or stability of the plasma in the hollow chamber 13 is therefore not influenced by the line width of the first perforation grooves TH1 and/or the opening ratio of the first mask M1.

(4) In contrast to the currently-used electron beam etching apparatus, FIB etching apparatus and excimer laser etching apparatus have an identical drawback of being unable to be applied to achieve large scale etching process, this non-contact physical etching system 1 can be adopted for treating the etching target 24 with a large-scale etching process as long as the first mask M1 and the second mask M2 have properly designed.

The above description is made on embodiments of the present invention. However, the embodiments are not intended to limit scope of the present invention, and all equivalent implementations or alterations within the spirit of the present invention still fall within the scope of the present invention.

What is claimed is:

1. A non-contact physical etching system, comprising:
a main body having an internal space;
a separation member, being disposed in the main body for partitioning the internal space into a first chamber and a second chamber;
a hollow chamber, being disposed on the separation member, and having a first opening located in the first chamber and a second opening located in the second chamber;
a first mask connected to the hollow chamber for shielding the second opening, wherein the first mask comprises a first metal substrate that are provided with a plurality of first perforation grooves thereon;
a target holder, being disposed in the second chamber for supporting at least one etching target;
a first vacuum pump, being connected to the first chamber for making the first chamber and the hollow chamber both have a first air pressure;
a second vacuum pump, being connected to the second chamber for making the second chamber has a second air pressure;
a plasma generating device, being connected to the first chamber; wherein the plasma generating device is adopted for supplying a plasma into the first chamber, or is configured for making a plasma be formed in the first chamber; and
a working gas supplying device, being connected to the first chamber and the plasma generating device;
wherein the plasma in the first chamber would flow into the hollow chamber via the first opening;
wherein the first mask is used as an exciting member of the plasma in the hollow chamber, such that the plasma is excited so as to produce a spontaneous electric field near a top surface of the first mask for achieving an electrical neutrality therein;
wherein a plurality of charges in the plasma are accelerated by the spontaneous electric field, so as to move and then pass through at least one first perforation pattern constituted by the plurality of first perforation grooves, thereby etching or cutting the etching target on the target holder by direct bombardment.

2. The non-contact physical etching system of claim 1, wherein each of the plurality of first perforation grooves has a groove width smaller than 100 μm.

3. The non-contact physical etching system of claim 1, wherein the first mask has an opening ratio smaller than 60%.

4. The non-contact physical etching system of claim 1, further comprising a second mask disposed between the first mask and the etching target, wherein the second mask comprises a second metal substrate that are provided with a plurality of second perforation grooves thereon.

5. The non-contact physical etching system of claim 4, wherein each of the plurality of second perforation grooves and each of the plurality of first perforation grooves have an overlooking shape selected from the group consisting of line shape, regular curve shape, irregular curve line shape, circle shape, oval shape, triangle shape, square shape, and polygonal shape.

6. The non-contact physical etching system of claim 4, wherein the plurality of second perforation grooves constitute a second perforation pattern.

7. The non-contact physical etching system of claim 6, wherein the second perforation pattern is the same as the first perforation pattern, such that the charged accelerated by the spontaneous electric field is converged by the second mask, so as to be prevented from being subject to lateral divergence.

8. The non-contact physical etching system of claim 6, wherein the second perforation pattern is different from the first perforation pattern, such that a relative intersection between the second perforation pattern and the first perforation pattern form a third perforation pattern.

9. The non-contact physical etching system of claim 6, further comprising a holder moving device, being used for driving the target holder to move corresponding to the first mask and/or the second mask.

10. The non-contact physical etching system of claim 6, further comprising an electrical field generating device, being electrically connected to the first mask, the second mask and the target holder.

11. The non-contact physical etching system of claim 1, wherein the first air pressure is greater than the second air pressure.

12. The non-contact physical etching system of claim 1, further comprising a magnetic field generating device, being configured for providing a magnetic field in the second chamber.

13. The non-contact physical etching system of claim 1, wherein there is a non-metallic sheath enclosing the first metal substrate of the first mask, and the non-metallic sheath having a plurality of through holes for making the plurality of first perforation grooves be exposed out of the non-metallic sheath.

14. The non-contact physical etching system of claim 1, further comprising a thermal dissipation device for applying a heat dissipating process to the hollow chamber, the target holder and the etching target.

15. The non-contact physical etching system of claim 1, further comprising an auxiliary device, wherein a detection unit of the auxiliary device disposed in the first chamber for measuring a temperature parameter and a plasma parameter.
